(19) United States
(12) Patent Application Publication
(10) Pub. No.: US 2018/0350787 A1
(43) Pub. Date: Dec. 6, 2018

(54) DISPLAY UNIT, DISPLAY DEVICE AND METHOD FOR MANUFACTURING DISPLAY UNIT

(71) Applicant: MITSUBISHI ELECTRIC CORPORATION, Chiyoda-ku, Tokyo (JP)

(72) Inventor: Satoru KIRIDOSHI, Tokyo (JP)

(73) Assignee: MITSUBISHI ELECTRIC CORPORATION, Chiyoda-ku, Tokyo (JP)

(21) Appl. No.: 15/562,219

(22) PCT Filed: Jan. 27, 2017
(86) PCT No.: PCT/JP2017/003055

§ 371 Date: Sep. 27, 2017

(51) Int. Cl. H01L 25/13; H01L 33/56; H01L 33/58; H05K 5/00; H05K 7/02; H05K 7/14; H05K 1/18

(52) U.S. Cl. CPC H01L 25/13; H01L 33/56; H01L 33/58; H05K 2201/10106; H05K 7/023; H05K 7/1422; H05K 1/181; H05K 5/0017

(57) ABSTRACT

The display unit includes a circuit board, a plurality of light emitting elements mounted on a mounting surface of the circuit board, a case on which the circuit board is placed, and a waterproof film covering the mounting surface of the circuit board, the plurality of light emitting elements and the case. The waterproof film and the case seal the mounting surface of the circuit board and the plurality of light emitting elements.

### TECHNICAL FIELD

The present disclosure relates to a display unit, a display device, and a method for manufacturing the display unit.

### BACKGROUND ART

A display device in which a plurality of display units are put together is known. Each display unit includes a circuit board and a plurality of light emitting elements mounted on the circuit board. The light emitting element, for example, is a light emitting diode (LED) element. The LED element is electrically connected to wiring formed on the circuit board.

The display unit includes a waterproofing material to prevent a short circuit of the wiring due to rainwater. For example, Patent Literature 1 discloses a display device in which silicone resin is filled around an LED element mounted on a circuit board. In addition, Patent Literature 2 discloses a display module in which a circuit board and an LED element mounted on the circuit board are attached in mold resin.

### CITATION LIST

### Patent Literature

Patent Literature 1: Unexamined Japanese Patent Application Kokai Publication No. H10-293540

Patent Literature 2: U.S. Pat. No. 9,172,929

### SUMMARY OF INVENTION

### Technical Problem

When silicone resin fills around the LED element, sealer resin is necessarily applied to the circuit board to prevent silicone resin from leaking out from the circuit board. In addition, the thickness of the filled silicone resin must be measured to adjust the thickness of the silicone resin. Furthermore, time for curing the silicone resin is necessary. With these processes, the number of steps for manufacturing display devices increases, and the production cost of the display device rises.

In addition, in the mold forming, production cost becomes higher because a mold depending on a size of the circuit board and an arrangement of the LED element are necessary.

The present disclosure is made with the view of the above situation and an objective of the present disclosure is to provide a display unit, a display device, and a method for manufacturing the display unit, the display unit and the display device being waterproof and capable of manufacturing more inexpensively than with conventional methods.

### Solution to Problem

The display unit according to the present disclosure includes a circuit board, a plurality of light emitting elements mounted on a mounting surface of the circuit board, a case on which the circuit board is placed, and a waterproof film covering the mounting surface of the circuit board, the plurality of light emitting elements, and the case. The waterproof film and the case seal the mounting surface of the circuit board and the plurality of light emitting elements.

The method for manufacturing a display unit according to the present disclosure includes:

reducing a pressure in a vacuum container in which a waterproof film and a case placing a circuit board on which a plurality of light emitting elements are mounted are set;

covering, using the waterproof film, the light emitting elements, the case, and a surface on which the light emitting elements on the circuit board are mounted; and

increasing a pressure in the vacuum container.

### Advantageous Effects of Invention

According to the present disclosure, the case and the waterproof film covering the mounting surface of the circuit board, the plurality of light emitting elements, and the case seal the mounting surface of the circuit board and the plurality of light emitting elements. Thus, the display unit can be made waterproof and can be manufactured more inexpensively than with than conventional methods.

### BRIEF DESCRIPTION OF DRAWINGS

FIG. 1 is a front elevation illustrating a display unit according to Embodiment 1 of the present disclosure;

FIG. 2 is a cross section of the display unit illustrated in FIG. 1 taken along the A-A line;

FIG. 3 is a cross section of the display unit illustrated in FIG. 1 taken along the B-B line;

FIG. 4 is a rear view illustrating the display unit according to Embodiment 1 of the present disclosure;

FIG. 5 is an exploded perspective view of a drive electric power source, a heat conduction sheet, and a unit cover of the display unit according to Embodiment 1 of the present disclosure;

FIG. 6 is a perspective view illustrating a case according to Embodiment 1 of the present disclosure;

FIG. 7 is a flowchart illustrating a manufacturing method of the display unit according to Embodiment 1 of the present disclosure;

FIG. 8 is a schematic diagram illustrating an arrangement of the case and a waterproof film in the manufacturing method of the display unit according to Embodiment 1 of the present disclosure;

FIG. 9 is a schematic diagram illustrating a covering by the waterproof film in the manufacturing method of the display unit according to Embodiment 1 of the present disclosure;

FIG. 10 is a cross section of a display unit according to Embodiment 2 of the present disclosure;

FIG. 11 is a cross section of a display unit according to Embodiment 3 of the present disclosure;

FIG. 12 is a schematic diagram illustrating a diffusion of external light on a waterproof film according to Embodiment 4 of the present disclosure;

FIG. 13 is a front elevation of a mask plate according to Embodiment 5 of the present disclosure;

FIG. 14 is a side view of the mask plate according to Embodiment 5 of the present disclosure;

FIG. 15 is a front elevation of a display unit according to Embodiment 5 of the present disclosure;

FIG. 16 is a cross section of the display unit illustrated in FIG. 15 taken along the C-C line;

FIG. 17 is a cross section of a display unit according to Embodiment 6 of the present disclosure;

FIG. 18 is a perspective view of a display device according to Embodiment 7 of the present disclosure;

FIG. 19 is a perspective view illustrating a chassis according to Embodiment 7 of the present disclosure;

FIG. 20 is a perspective view illustrating a longitudinal frame according to Embodiment 7 of the present disclosure; and

FIG. 21 is a perspective view illustrating a transverse frame according to Embodiment 7 of the present disclosure.

### DESCRIPTION OF EMBODIMENTS

A display unit and a display device according to an embodiment of the present disclosure is described hereafter with reference to the drawings.

### Embodiment 1

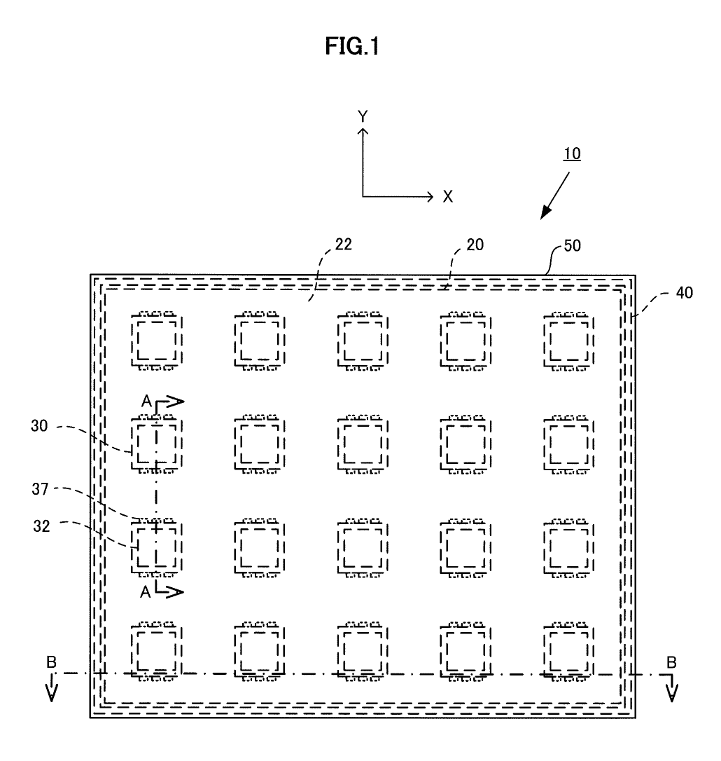

With reference to FIGS. 1 through 9, a display unit 10 according to Embodiment 1 of the present disclosure is described. For easier understanding, the display unit 10 is described assuming that the front of the display unit 10 is vertically set with respect to the ground outdoors, taking a direction that is parallel to the ground and the front of the display unit 10 as X-axis direction, a direction perpendicular to the ground as Y-axis direction, and a direction perpendicular to the X-axis direction and the Y-axis direction as Z-axis direction. The definition of these axis directions is the same in the other embodiments.

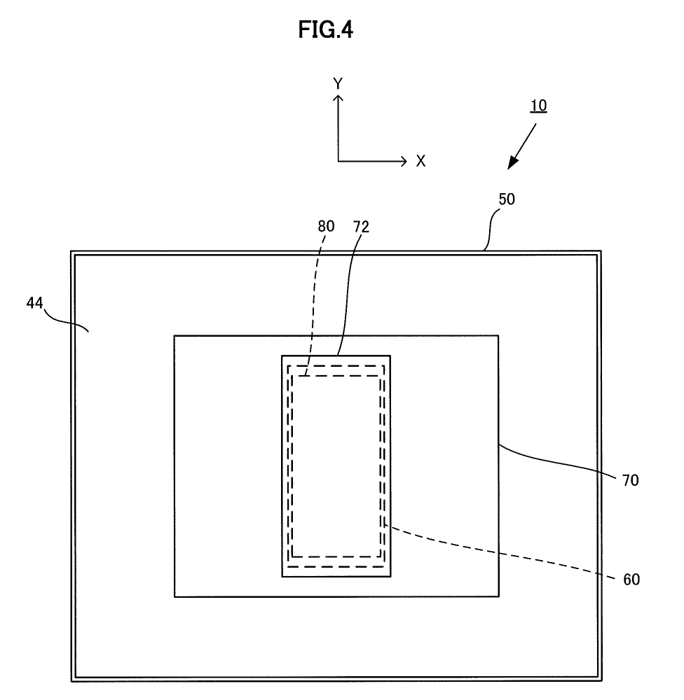

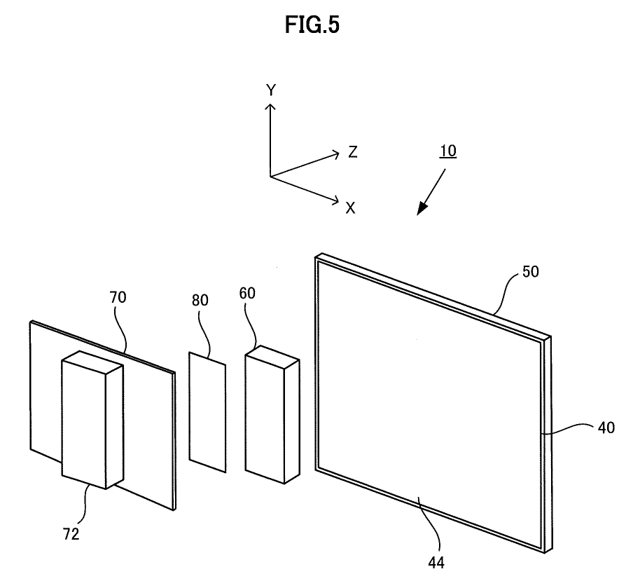

As illustrated in FIGS. 1 through 3, the display unit 10 includes a circuit board 20, a plurality of light emitting elements 30 mounted on a mounting surface 22 of the circuit board 20, a case 40 on which the circuit board 20 is placed, and a waterproof film 50 covering the mounting surface 22, the plurality of light emitting elements 30, and the case 40. Furthermore, as illustrated in FIGS. 4 and 5, the display unit 10 includes a drive electric power source 60 supplying electric power to the light emitting element 30, a unit cover 70 protecting components such as the circuit board 20, the drive electric power source 60 and the like, and a heat conduction sheet 80 conducting heat generated by the circuit board 20 and the drive electric power source 60 to the unit cover 70. The display unit 10 is set outdoors such as in a sports stadium, on wall surfaces of buildings, and/or the like.

The circuit board 20 is made of an insulating resin material. The circuit board 20 includes wiring (not illustrated) that supplies electric power to the light emitting element 30. In addition, a non-illustrated drive Integrated Circuit (IC) is provided on the circuit board 20, electric power is supplied to the drive IC from the drive electric power source 60, and the drive IC drives the light emitting element 30 through the wiring of the circuit board 20.

The light emitting element 30, for example, is a surface mount type LED element of the 3-in-1 type. The light emitting element 30 is arranged in a 4-by-5 matrix on the mounting surface 22 of the circuit board 20. The light emitting element 30 includes a light emitting surface 32 that emits light onto a flat top surface 31. In addition, a surface arranged on the front side of the display unit 10 in the light emitting element 30 is defined as the top surface 31 of the light emitting element 30, and a surface perpendicular to the mounting surface 22 of the circuit board 20 is defined as a lateral surface 33 of the light emitting element 30.

The light emitting element 30 includes three light-emitting chips (not illustrated), a package 35 in which light-emitting chips are mounted, a sealed portion 36 sealing the light-emitting chips in the package 35, and six electrodes 37 supplying electric power to each of the light-emitting chips.

The three light-emitting chips emit red light, green light, and blue light respectively. The emission intensity of the three light-emitting chips is independently adjusted by the electric power supplied to each of the light-emitting chips through the wiring of the circuit board 20 from the drive IC of the circuit board 20. In this way, from the light emitting element 30, light of any color is emitted at any intensity. As a result, a color image is displayed on the display unit 10 by the plurality of light emitting elements 30.

The package 35, for example, is made of white resin. The light-emitting chips are mounted in the concave portion of the package 35. The sealed portion 36 is a sealing resin filled in the concave portion of the package 35, and the sealed portion 36 seals the three light-emitting chips. The sealing resin, for example, is translucent resin such as silicone resin, epoxy resin, acrylic resin, polyester resin, and the like. The electrodes 37 in pairs, including a positive electrode and a negative electrode, connect to each of the light-emitting chips, and supply electric power to each of the light-emitting chips. The electrodes 37 are electrically connected to the wiring of the circuit board 20 by soldering.

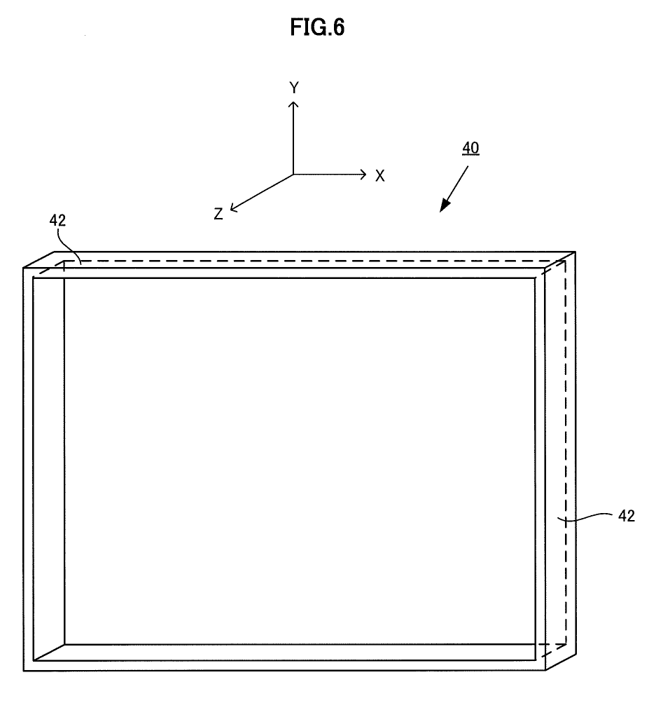

The case 40, as illustrated in FIG. 6, is a box-like chassis with an open surface in the Z-axis direction. The case 40 is made of resin such as polycarbonate resin, acrylic resin or the like. The circuit board 20, on which the light emitting element 30 is mounted, is placed on the case 40, as illustrated in FIG. 3, with the mounting surface 22 of the circuit board 20 directed towards the opened direction of the chassis.

The waterproof film 50 is made of translucent resin such as polyester resin, polycarbonate resin, acrylic resin, the olefin resin, and the like. In addition, the waterproof film 50 is soft and flexible. The thickness of the waterproof film 50 is, for example, 50 μm to 500 μm, preferably 150 μm to 300 μm from the viewpoint of flexibility and durability.

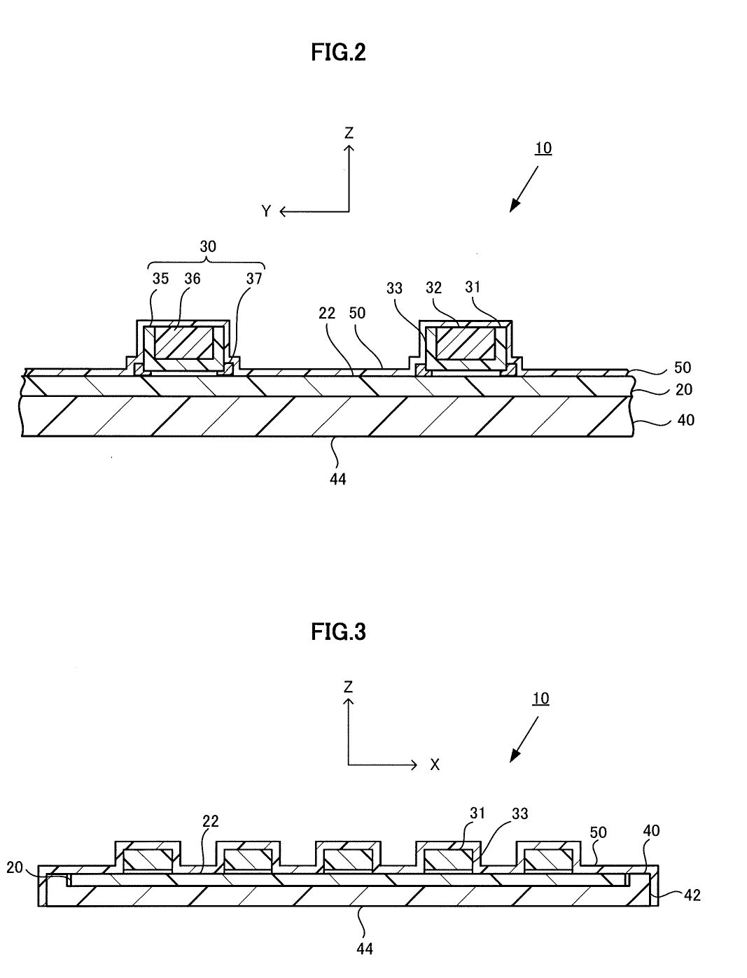

As illustrated in FIGS. 2 and 3, the waterproof film 50 covers the mounting surface 22 on the circuit board 20, the mounted light emitting element 30, and the case 40 along the top surface 31 and the lateral surface 33 of the mounted light emitting element 30, the mounting surface 22, and a lateral surface 42 of the case 40. The waterproof film 50 and the case 40, in this way, seal the mounting surface 22 of the circuit board 20 and the light emitting element 30. In addition, in the present embodiment, the waterproof film 50 closely contacts the top surface 31 and the lateral surface 33 of the light emitting element 30, the mounting surface 22 of the circuit board 20 and the lateral surface 42 of the case 40.

Because the waterproof film 50 and the case 40 seal the mounting surface 22 of the circuit board 20 and the light emitting element 30, the display unit 10 can be waterproofed. In addition, the waterproof film 50 covers the mounting surface 22 of the circuit board 20, the light emitting element 30 and the case 40, and seals the mounting surface 22 of the circuit board 20 and the light emitting element 30. Thus the display unit 10 is waterproofed and inexpensively manufactured in a number of steps less than a conventional method of filling silicone resin around the LED element. For example, in the production of the display unit 10, a step of preventing a leak of the waterproofing resin, a step of adjusting the thickness of the waterproofing resin, a step of curing the waterproofing resin, and the like become unnecessary.

Furthermore, degradation over time of the case 40 can be suppressed because the waterproof film 50 covers the case 40.

The drive electric power source 60, as illustrated in FIGS. 4 and 5, is provided on an external bottom surface 44 of the case 40. The drive electric power source 60 is connected to the drive IC of the circuit board 20 by wiring through a through-hole (not illustrated) in the case 40. In addition, the drive electric power source 60 is connected to an external electric power source (not illustrated). The drive electric power source 60 supplies electric power for driving the light emitting element 30 to the drive IC. In addition, the through-hole provided in the case 40 is sealed by a sealing material.

The unit cover 70 stores the drive electric power source 60 and the heat conduction sheet 80 in a concave portion 72 and is screwed on the bottom surface 44 of the case 40. A space between the unit cover 70 and the bottom surface 44 of the case 40 is sealed with a sealing material such as the silicon rubber packing and the like, and the unit cover 70 and the case 40 waterproof the drive electric power source 60. In addition, the unit cover 70 radiates heat generated by the circuit board 20 and the drive electric power source 60.

The heat conduction sheet 80 is interposed between the drive electric power source 60 and the unit cover 70, and conducts the heat generated by the circuit board 20 and the drive electric power source 60 to the unit cover 70. The heat conduction sheet 80, for example, is made of resin such as silicone resin, acrylic resin, or the like.

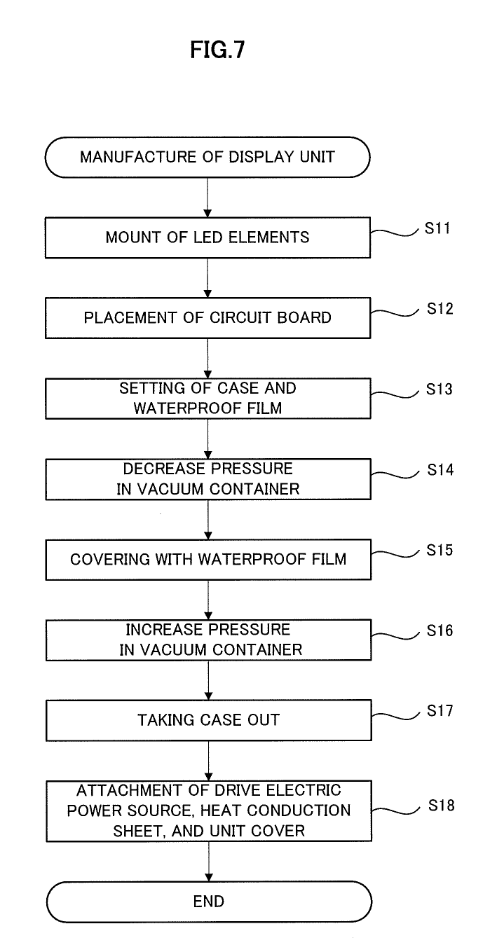

Next, with reference to FIGS. 7 to 9, the manufacturing method of the display unit 10 is described.

FIG. 7 is a flow chart illustrating the manufacturing method of the display unit 10. First, the circuit board 20 with the wiring and the waterproof film 50 are prepared. Then, the electrodes 37 of the light emitting element 30 are soldered to the wiring of the circuit board 20 using the reflow method, and each of the light emitting elements 30 are mounted on the mounting surface 22 of the circuit board 20 (step S11).

Next, the circuit board 20, on which the light emitting element 30 is mounted, is placed on the case 40 (step S12).

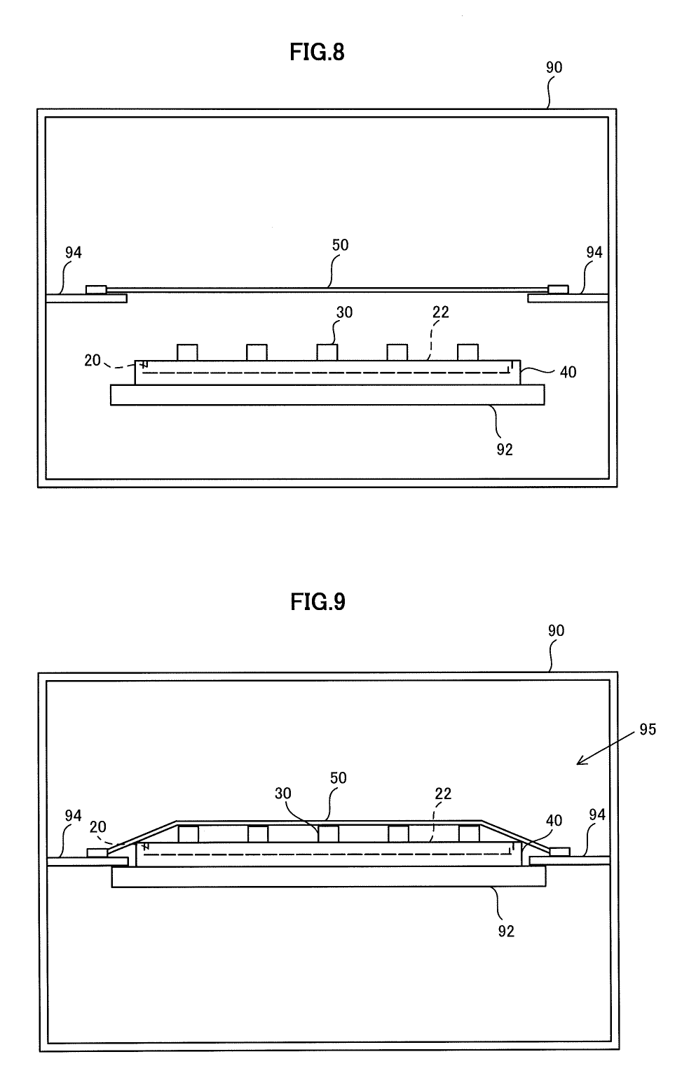

The case 40 on which the circuit board 20 is placed and the waterproof film 50 are set in a vacuum container 90 as illustrated in FIG. 8 (step S13). Then, the vacuum container 90 is deaerated and pressure therein is reduced (step S14). Then the inside of the vacuum container 90 is preferably heated by a heater (not illustrated).

As illustrated in FIG. 9, a table 92, with the case 40 placed, is raised in the vacuum container 90, and the mounting surface 22 of the circuit board 20, the light emitting element 30 and the case 40 is covered with the waterproof film 50 (step S15). In addition, the raised table 92 and a convex portion 94 provided in the vacuum container 90 on the entire periphery of the vacuum container 90 seal an area 95 that is the upper half of the inside of the vacuum container 90 in which the case 40 placing the circuit board 20 and the waterproof film 50 are positioned.

Next, the inside of the area 95 is pressurized by sending air to the area 95 in the vacuum container 90, and the waterproof film 50 is attached by the pressure onto the mounting surface 22 of the circuit board 20 and the light emitting element 30 (step S16). The waterproof film 50 in this way closely contacts the top surface 31 and the lateral surface 33 of the light emitting element 30, the mounting surface 22 of the circuit board 20, and the lateral surface 42 of the case 40. The waterproof film 50 and the case 40 in this way seal the mounting surface 22 of the circuit board 20 and the light emitting element 30.

The pressure in the vacuum container 90 is returned to a normal pressure, and the case 40 covered with the waterproof film 50 is taken out from the vacuum container 90 (step S17). Finally, the drive electric power source 60, the heat conduction sheet 80, and the unit cover 70 are attached to the case 40 (step S18).

In this way, the display unit 10 can be manufactured.

As mentioned above, the display unit 10 is waterproofed by the waterproof film 50 and the case 40. In addition, the waterproof film 50 covers the mounting surface 22 of the circuit board 20, the light emitting element 30, and the lateral surface 42 of the case 40, and seals the mounting surface 22 of the circuit board 20 and the light emitting element 30. Therefore, the display unit 10 can be waterproofed in the reduced number of steps. The display unit 10 is inexpensively manufactured.

### Embodiment 2

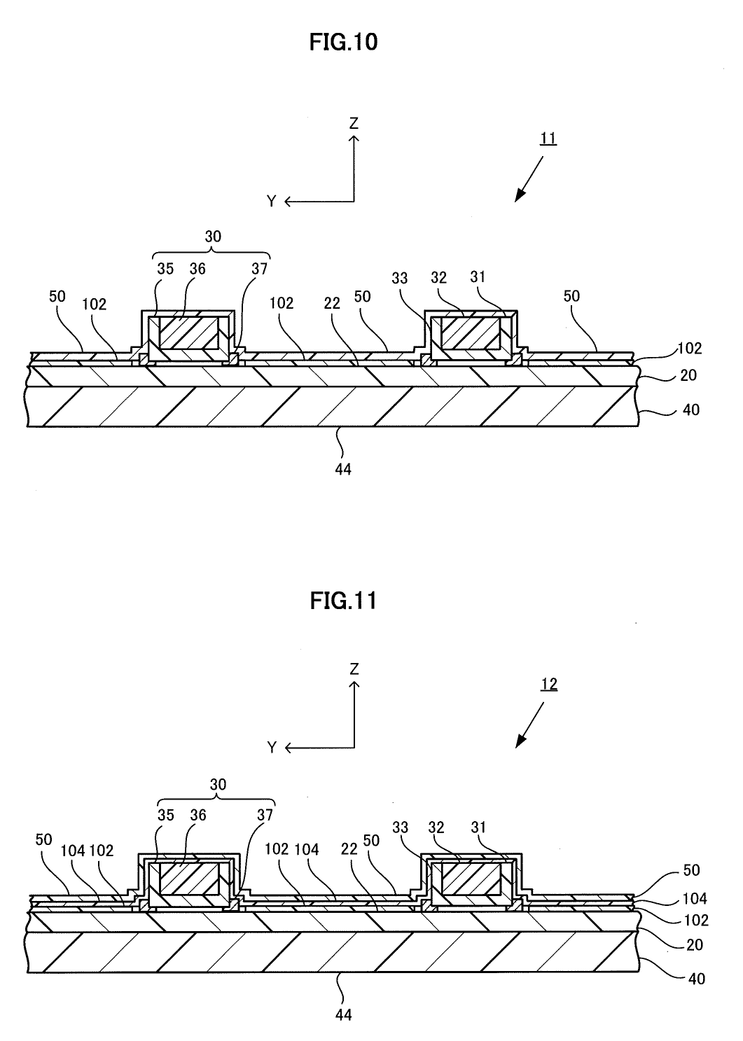

With reference to FIG. 10, a display unit 11 according to Embodiment 2 is described.

In Embodiment 1, the waterproof film 50 directly contacts with the mounting surface 22 of the circuit board 20. However, a sticky material may be provided between the mounting surface 22 and a surface 52 of the waterproof film 50 facing the mounting surface 22.

As illustrated in FIG. 10, the display unit 11 includes an sticky layer 102 between the surface 52 of the waterproof film 50 facing the mounting surface 22 of the circuit board 20 and the mounting surface 22 of the circuit board 20. The waterproof film 50 closely contacts the mounting surface 22 of the circuit board 20 via the sticky layer 102. Other configurations are similar to Embodiment 1.

The sticky layer 102 is formed by applying a silicone adhesive to a portion of the mounting surface 22 of the circuit board 20 where the light emitting element 30 is not mounted on. The application of the silicone adhesive is performed before setting the case 40 in the vacuum container 90 in the manufacturing method of the display unit 10 in Embodiment 1.

As mentioned above, the waterproof film 50 closely contacts the mounting surface 22 of the circuit board 20 via the sticky layer 102 in the display unit 11. Thus, the waterproof film 50 more strongly and closely contacts the top surface 31 and the lateral surface 33 of the light emitting element 30, the mounting surface 22 of the circuit board 20, and the lateral surface 42 of the case 40. Therefore, similar to the display unit 10 of Embodiment 1, the display unit 11 is waterproofed and inexpensively manufactured. In addition, the durability of the display unit 11 improves. Furthermore, the surface reflection of light emitted from the light emitting element 30 on the waterproof film 50 decreases, and the display unit 11 can display a brighter image.

### Embodiment 3

With reference to FIG. 11, a display unit 12 according to Embodiment 3 is described.

A material provided between the surface 52 of the waterproof film 50 and the mounting surface 22 of the circuit board 20 is not limited to the sticky layer 102.

The display unit 12 includes a primer layer 104 between the surface 52 of the waterproof film 50 and the sticky layer 102. The primer layer 104 is a primer agent chosen depending on the waterproof film 50 and the sticky layer 102 being a material to be closely contacted, and the primer layer 104 improves adhesiveness of the surface 52 of the waterproof film 50. Other configurations are similar to that of Embodiment 2.

The primer layer 104 is formed by applying a primer agent to the surface 52 of the waterproof film 50, and being dried. The formation of the primer layer is performed before setting the waterproof film 50 in the vacuum container 90 in the manufacturing method of the display unit 10 in Embodiment 1.

The adhesiveness of the waterproof film 50 is improved in the display unit 12. Thus, the waterproof film 50 more strongly and closely contacts the top surface 31 and the lateral surface 33 of the light emitting element 30, the mounting surface 22 of the circuit board 20, and the lateral surface 42 of the case 40. Therefore, similar to the display unit 10 of Embodiment 1, the display unit 12 is waterproofed and inexpensively manufactured. In addition, the durability of the display unit 12 improves. Furthermore, the display unit 12 can display a brighter image.

### Embodiment 4

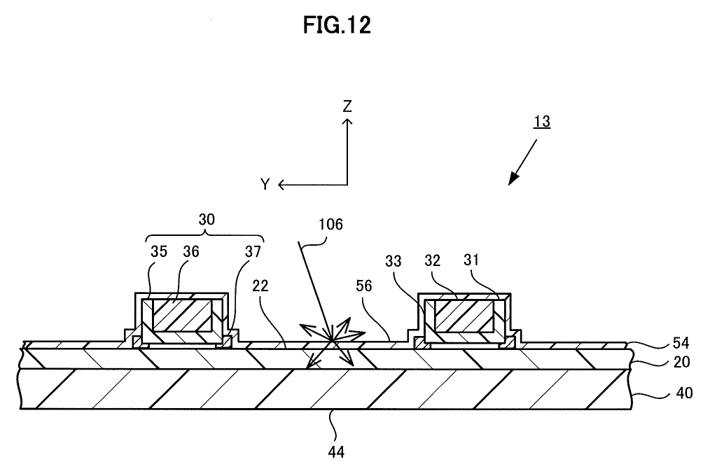

With reference to FIG. 12, a display unit 13 according to Embodiment 4 is described.

In Embodiment 1 through Embodiment 3, the waterproof film 50 is translucent. The display unit 13 includes a waterproof film 54 having a light diffusion property with translucency instead of the waterproof film 50. Other configurations are similar to that of Embodiment 1.

The waterproof film 54 is performed the emboss processing on a surface 56 on the front side of the display unit 13. In addition, the surface 56 of the waterproof film 54 is a surface of the waterproof film 54 on the opposite side of the surface 52 facing the mounting surface 22 of the circuit board 20.

As the surface 56 of the waterproof film 54 is performed the emboss processing, the waterproof film 54 diffuses external light 106, which is incident on the display unit 13, as illustrated in FIG. 12. This can suppress a drop in contrast of an image displayed on the display unit 13 caused by the display unit 13 reflecting the external light 106. In addition, the external light 106 includes sunlight and illumination that enters the display unit 13 from around the display unit 13.

The display unit 13, as mentioned above, can suppress a drop in the contrast of the displayed image because the waterproof film 54 diffuses the external light 106. In addition, the display unit 13 is waterproofed and is inexpensively manufactured similar to the display unit 10 of Embodiment 1.

### Embodiment 5

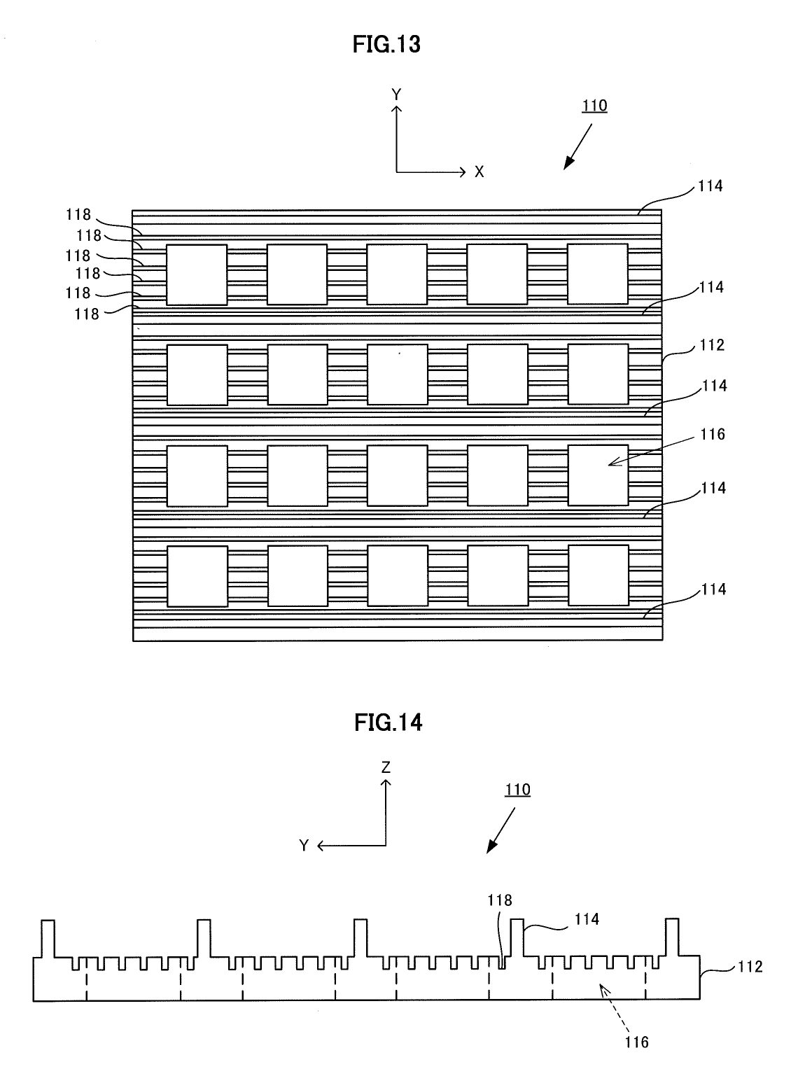

With reference to FIGS. 13 through 16, a display unit 14 according to Embodiment 5 is described.

In Embodiment 4, the waterproof film 54 diffuses the external light 106 and controls the drop in the contrast of the image. The display unit 14 according to the present embodiment controls a drop in contrast of an image by using other materials.

The display unit 14 includes a mask plate 110. The other configurations are similar to that of Embodiment 1.

The mask plate 110, as illustrated in FIGS. 13 and 14, includes a tabular body portion 112 and an eaves portion 114 projected from the body portion 112 in the front direction of the display unit 14. The body portion 112 of the mask plate 110 has rectangular openings 116 at a position corresponding to the light emitting element 30 mounted on the mounting surface 22 of the circuit board 20. The openings 116 are formed so as to be greater than a horizontal size of the light emitting element 30 for inserting the light emitting element 30. In addition, the body portion 112 of the mask plate 110 has a groove portion 118 extending in the X-axis direction between the openings 116.

The mask plate 110, for example, is made from black resin by injection molding.

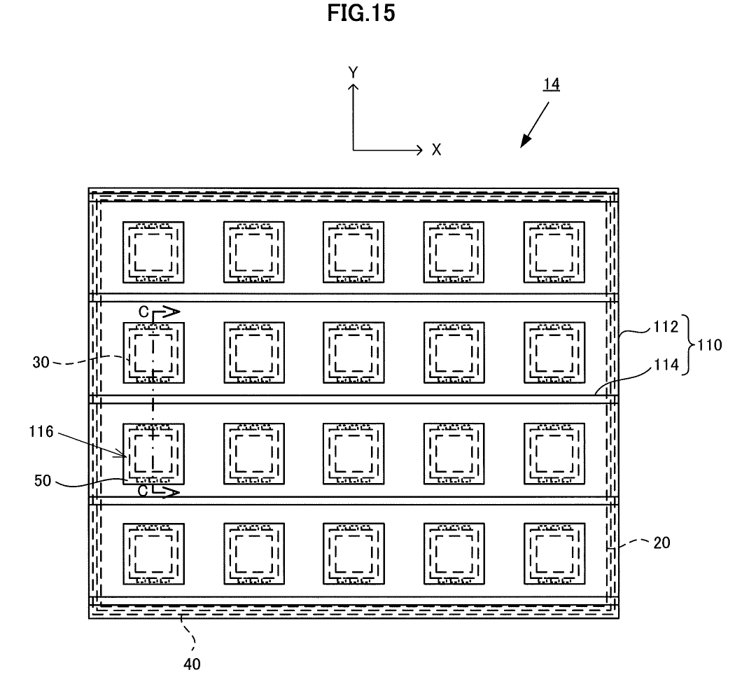

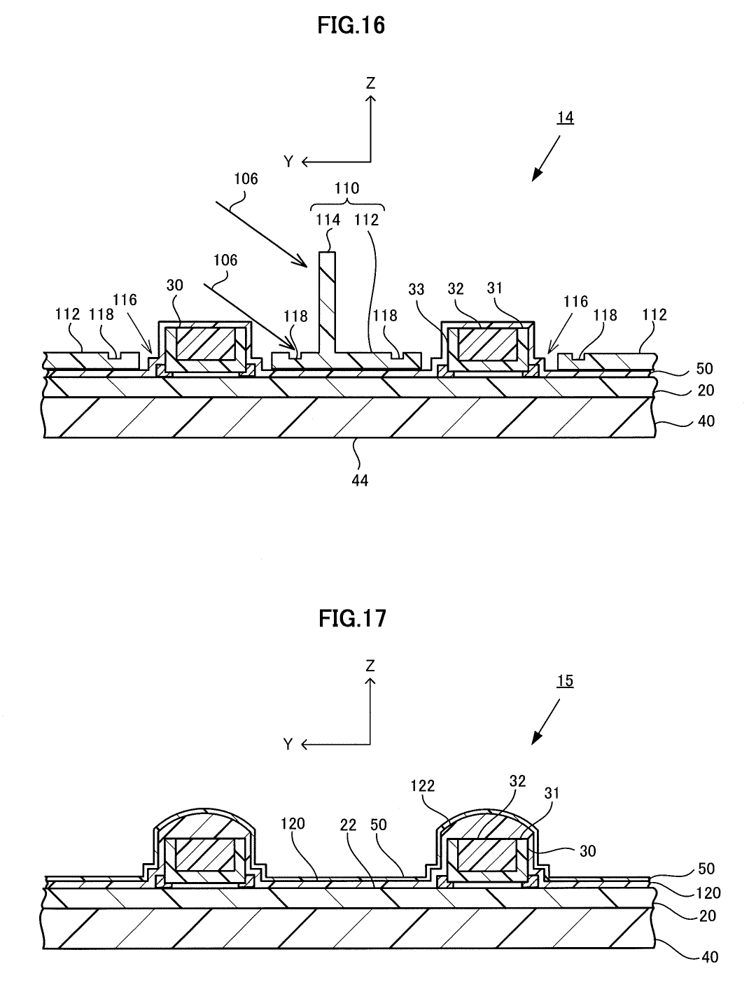

The mask plate 110, as illustrated in FIGS. 15 and 16, is provided on the waterproof film 50 in a state in which each of the light emitting elements 30 is inserted in the corresponding openings 116. The mask plate 110 is screwed in the circuit board 20. In addition, in FIG. 15, the groove portion 118 is omitted to facilitate easy understanding.

The mask plate 110 controls the drop in the contrast of the image displayed on the display unit 14 by blocking the external light 106. Blocking the external light 106 means controlling the external light 106 that otherwise enter the circuit board 20 and the light emitting element 30. For example, the body portion 112 of the mask plate absorbs the external light 106 entering the circuit board 20. The groove portion 118 of the body portion 112 diffuses or reflects the external light 106. Furthermore, the eaves portion 114 of the mask plate 110 diffuses or reflects the external light 106 which is otherwise enters the light emitting element 30.

As mentioned above, as the mask plate 110 blocks the external light 106, the display unit 14 can control the drop in the contrast of the displayed image. In addition, the display unit 14 is waterproofed and inexpensively manufactured similar to the display unit 10 of Embodiment 1.

### Embodiment 6

With reference to FIG. 17, a display unit 15 according to Embodiment 6 is described.

In Embodiments 2 and 3, the display units 11 and 12 include a material between the surface 52 of the waterproof film 50 and the mounting surface 22 of the circuit board 20 for improving adhesiveness between the surface 52 and the mounting surface 22. The material provided between the surface 52 of the waterproof film 50 and the mounting surface 22 of the circuit board 20 is not limited to a material that improves adhesiveness between the surface 52 and the mounting surface 22.

The display unit 15, as illustrated in FIG. 17, includes a microlens sheet 120 between the surface 52 of the waterproof film 50 and the mounting surface 22 of the circuit board 20. Other configurations are similar to that of Embodiment 1.

The microlens sheet 120 includes a microlens 122 at a position corresponding to the top surface 31 of the light emitting element 30 mounted on the mounting surface 22 of the circuit board 20. The microlens sheet 120 is made of, for example, polycarbonate resin, olefin resin, or the like. The thickness of the microlens sheet 120 is, for example, 200 μm through 500 μm. The microlens sheet 120 is attached by the pressure to the mounting surface 22 and the light emitting element 30 in a manner similar to the pressure attaching of the waterproof film 50 to the mounting surface 22 and the light emitting element 30 in Embodiment 1 (step S13 through step S16).

The microlens 122 gathers light emitted from the light emitting surface 32 of the light emitting element 30.

As the microlens 122 gathers light emitted from the light emitting element 30, the display unit 15 can display a brighter image. In addition, a viewing angle of the display unit 15 can be adjusted depending on how the display unit 15 is used by adjusting a refractive index and a shape of the microlens 122. The display unit 15 is waterproofed and inexpensively manufactured similar to the display unit 10 of Embodiment 1. Furthermore, the durability of the microlens sheet 120 improves because the waterproof film 50 covers the microlens 122.

### Embodiment 7

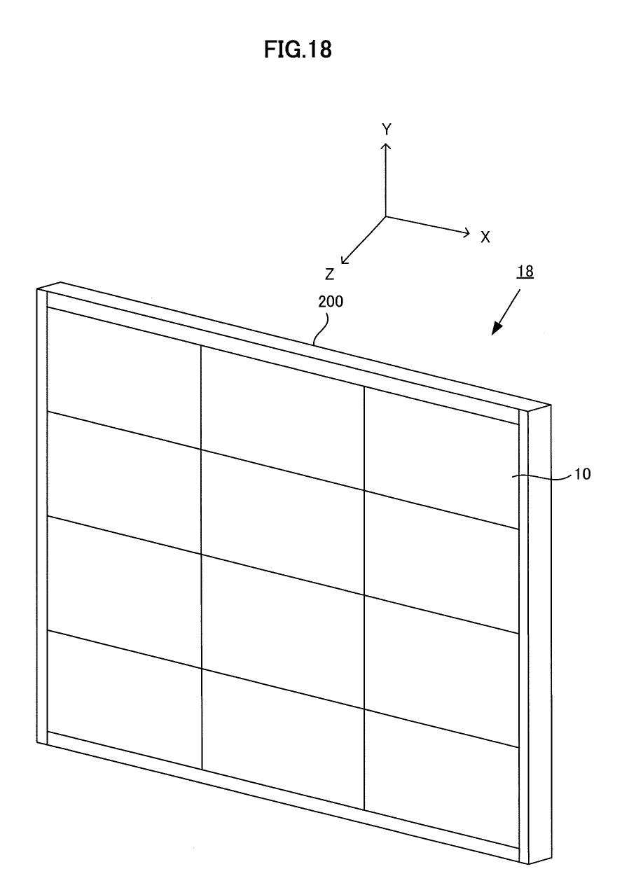

With reference to FIGS. 18 through 21, a display device 18 according to Embodiment 7 is described.

The larger display device 18 can be configured by combining a plurality of the display units 10 through 15 together. The display device 18 is set outdoors such as on a wall surface of a sports stadium, a building, or the like.

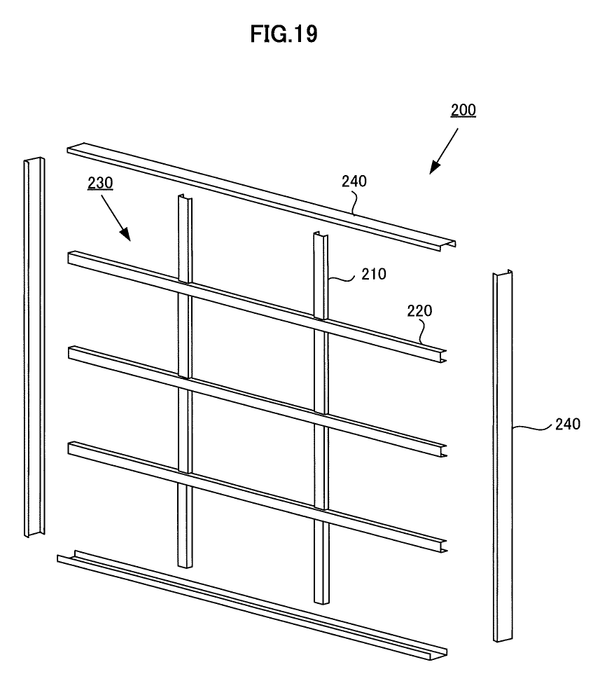

As illustrated in FIG. 18, the display device 18, for example, includes twelve display units 10 and a chassis 200 that stores these twelve display units 10. The chassis 200 has a grid frame 230 and an external frame 240 as illustrated in FIG. 19.

The twelve display units 10 are arranged to form a 4-by-3 matrix. The arranged display units 10 are held in the grid frame 230 by fasteners.

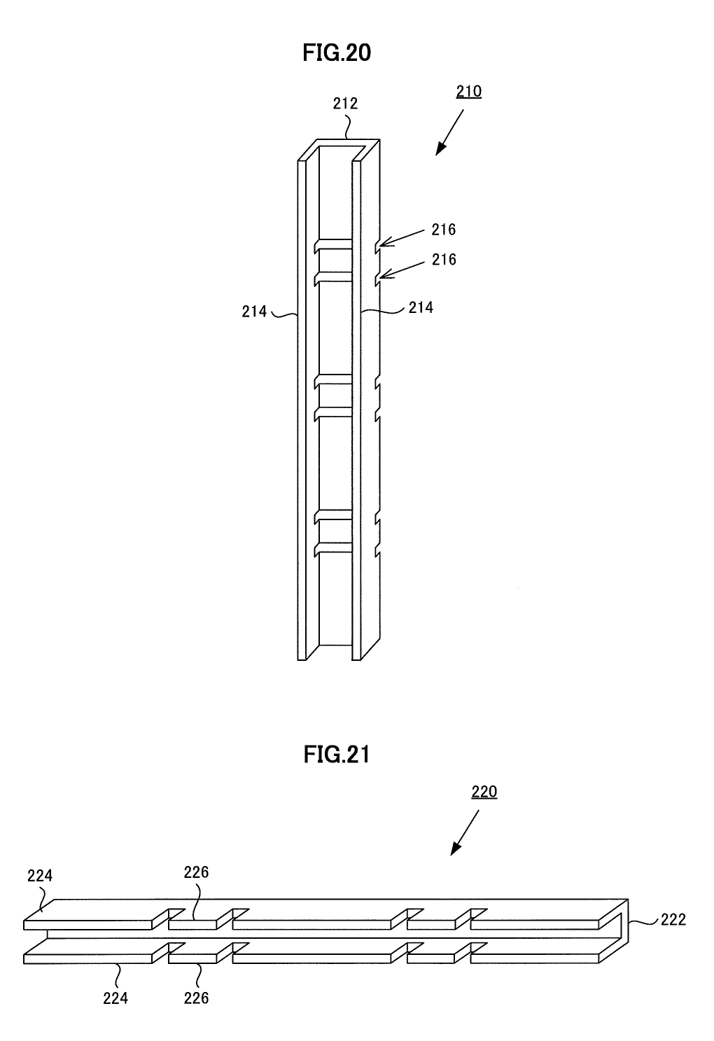

The grid frame 230 is formed of combining longitudinal frames 210 and transverse frames 220. The cross section of the longitudinal frame 210, as illustrated in FIG. 20, is channel shaped. The longitudinal frame 210 includes a slit 216 having a channel shaped cross section that is formed by cutting out portions of a bottom plate 212 and a side plate 214. The cross section of the transverse frame 220, as illustrated in FIG. 21, is channel shaped. The transverse frame 220 includes an insertion portion 226 that is formed by cutting out a side plate 224 from the end face of the side plate 224 in the direction towards a bottom plate 222. The longitudinal frames 210 and the transverse frame 220 are assembled to form the grid frame 230 as illustrated in FIG. 19 by fitting the insertion portion 226 of the transverse frame 220 in the slit 216 of the longitudinal frames 210. The arranged display unit 10, for example, is screwed to the transverse frame 220 of the grid frame 230.

The external frames 240 are fixed to each other by screws or welding and surround the grid frame 230 and the display unit 10 held by the grid frame 230.

The display device 18 is formed of the waterproofed display unit 10, thus, can be waterproofed without separately providing waterproof materials such as a waterproofing door, a box-shaped chassis, or the like. Therefore, a waterproofed large-sized display device 18 can be inexpensively manufactured. In addition, as the case chassis 200 is formed of the grid frame 230 and the external frame 240, the weight of the large-sized display device 18 can be reduced. Furthermore, the grid frame 230 holding the display unit 10 is assembled by fitting the transverse frame 220 in the longitudinal frames 210. Thus, the assembling is easy and the display device 18 can be inexpensively manufactured.

As mentioned above, Embodiments of the present disclosure are described. The embodiments described above do not limit the scope of the present disclosure. Moreover, the present disclosure can undergo various modifications without departing from the broad spirit and scope of the disclosure.

The light emitting element 30, for example, is not limited to an LED element, but may be a laser diode (LD). In addition, the LED element is not limited to a surface mount type LED element, but may be a bullet shaped LED element. The light emitting element 30 is not limited to the 3-in-1 type. The light emitting element 30 may be a light emitting element emitting monochromatic light in which one light emitting element is mounted in one package 35. In addition, the light emitting element 30 may include four or more light-emitting chips. The color of the package 35 is not limited to white, and the color may be black. As the light emitting element 30 including a black package 35 absorbs the external light 106, the contrasts of the images displayed on the display units 10 through 15 and the display device 18 are improved.

The light emitting element 30 mounted on the circuit board 20 is arranged not only in a 4-by-5 matrix, but also arranged in any arrangement. For example, the light emitting element 30 may be mounted on the circuit board 20 arranged in a 128-by-128 matrix or 256-by-256 matrix. In addition, the light emitting element 30 may be arranged in a rhombic lattice, a hexagon lattice, a rectangular lattice, a hound's-tooth, or the like. Any spacing can be set between the light emitting elements 30. Furthermore, a space where no light emitting element 30 is arranged may be provided on the mounting surface 22 of the circuit board 20.

The waterproof films 50 and 54 are preferably thermoplastic. When the display units 10 through 15 are manufactured, the thermoplastic waterproof films 50 and 54 can be easily attached by the pressure to the mounting surface 22 of the circuit board 20 and the light emitting element 30 by heating the thermoplastic waterproof films 50 and 54 with a heater. Furthermore, the waterproof films 50 and 54 are preferably weather-resistant.

The waterproof films 50 and 54 may be colored and translucent films. The color of the waterproof films 50 and 54 is preferably achromatic from the viewpoint of color reproduction characteristics. In addition, from the viewpoint of controlling a reflection of the external light 106, the transmittance of the waterproof films 50 and 54 for visible light is preferably 40% through 99%. The transmittance of the waterproof films 50 and 54 for visible light can be adjusted, for example, by an amount of a coloring agent such as carbon black, dye composition and/or the like to be added in the waterproof films 50 and 54. Furthermore, the waterproof films 50 and 54 may contain a light diffusion agent made of acrylic resin, polycarbonate resin, or the like, not only by the emboss described in Embodiment 4, and may diffuse the external light 106. The waterproof films 50 and 54 can seal the mounting surface 22 and the light emitting element 30 by covering the mounting surface 22 of the circuit board 20, the light emitting element 30, and the case 40 placing the circuit board 20, without closely contacting to the mounting surface 22 and the light emitting element 30.

Not only a silicone adhesive but also an acrylic adhesive, an urethane adhesive, or the like may be applied to form the sticky layer 102. The adhesive is preferably an additive curing type adhesive. As the additive curing type adhesive is cured by heat, the thermoplastic waterproof film 50, the mounting surface 22 of the circuit board 20, and the light emitting element 30 can be easily and closely contacted by heating, when the thermoplastic waterproof films 50 and 54 are attached by the pressure to the mounting surface 22 of the circuit board 20 and the light emitting element 30. In addition, the sticky layer 102 may be provided between surfaces 52 of the waterproof films 50 and 54 and the light emitting element 30. The sticky layer 102 may be provided between the surfaces 52 of the waterproof films 50 and 54 and the lateral surface 42 of the case 40. Furthermore, the adhesive may be applied to the surfaces 52 of the waterproof films 50 and 54 instead of being applied to the mounting surface 22 of the circuit board 20 described in Embodiment 2. Furthermore, the display units 10 through 15 may include an adhesive layer instead of the sticky layer 102. For example, silicone adhesive, acrylic adhesive, or urethane adhesive is applied to form the adhesive layer.

The primer layer 104 may be applied to the mounting surface 22 of the circuit board 20 to improve adhesiveness of the mounting surface 22. In addition, the primer layer 104 may directly contact the surfaces 52 of the waterproof films 50 and 54 and the mounting surface 22 of the circuit board 20 to improve the adhesiveness between the surfaces 52 of the waterproof films 50 and 54 and the mounting surface 22. In addition, the adhesiveness of the mounting surface 22 of the circuit board 20 may be improved by plasma processing at least one of the mounting surface 22 and the surfaces 52 of the waterproof films 50 and 54. The surfaces 52 of the waterproof films 50 and 54 may be plasma processed.

The mask plate 110 may include the openings 116 without including the eaves portion 114 and the groove portion 118. In addition, the mask plate 110 may be a plate provided between the light emitting elements 30, and may functions as eaves of the light emitting element 30.

The microlens sheet 120 may be provided on the surfaces 56 of the waterproof films 50 and 54, not being limited to a space between the surfaces 52 of the waterproof films 50 and 54 and the mounting surface 22 of the circuit board 20.

Any number of display units 10 may be arranged to form the display device 18 in any arrangement. In addition, the display device 18 may include the display units 11 through 15 instead of the display unit 10. The display units 10 through 15 may be held in the grid frame 230 not only by being screwed, which is described in Embodiment 7, but also by a rotary latch provided in the case 40. For example, the display units 10 through 15 are fixed to the transverse frame 220 of the grid frame 230 by a rotary latch. The grid frame 230 in the display device 18 may be assembled by inserting side plates 214 and 224 in a slit provided in either of the other side plate 214 of the longitudinal frame 210 or the other side plate 224 of the transverse frame 220.

The display units 10 through 15 and the display device 18 may be set not only outdoors, but also in indoors such as a in a gymnasium, an indoor pool, and the like.

In manufacturing the display unit 10, after the mounting surface 22 of the circuit board 20, the light emitting element 30, and the case 40 are covered with the waterproof films 50 and 54, not only the area 95 in the vacuum container 90 but also the entire inside of the vacuum container 90 may be pressurized and may return to an normal pressure. In addition, in the vacuum container 90, the waterproof films 50 and 54 may be rolled out over the case 40 from the roll of the waterproof films 50 and 54, and after the waterproof films 50 and 54 are attached by the pressure to the mounting surface 22 of the circuit board 20 and the light emitting element 30, the attached waterproof films 50 and 54 may be cut off by a cutter or the like (not illustrated) from the roll around which the waterproof films 50 and 54 are rolled.

### REFERENCE SIGNS LIST

10 Display unit
11, 12, 13, 14, 15 Display unit
18 Display device
20 Circuit board
22 Mounting surface
30 Light emitting element
31 Top surface
32 Light emitting surface
33, 42 Lateral surface
35 Package
36 Sealed portion
37 Electrode
40 Case
44 Bottom surface
50, 54 Waterproof film
52 Surface facing mounting surface of circuit board of waterproof film
56 Front side surface of waterproof film
60 Drive electric power source
70 Unit cover
72 Concave portion
80 Heat conduction sheet
90 Vacuum container
92 Table
94 Convex portion
95 Area
102 Sticky layer
104 Primer layer
106 External light
110 Mask plate
112 Body portion
114 Eaves portion
116 Opening
118 Groove portion
120 Microlens sheet
122 Microlens
200 Chassis
210 Longitudinal frame
212, 222 Bottom plate
214, 224 Side plate
216 Slit
226 Insertion portion
220 Transverse frame
230 Grid frame
240 Outside frame

1. A display unit comprising:
a circuit board;
a plurality of light emitting elements mounted on a mounting surface of the circuit board, a case on which the circuit board is placed; and
a waterproof film covering the mounting surface of the circuit board, the plurality of light emitting elements, and the case;
wherein the waterproof film and the case seal the mounting surface of the circuit board and the plurality of light emitting elements.

2. The display unit according to claim 1, wherein one surface of the case is open.

3. The display unit according to claim 1, wherein the waterproof film is flexible.

4. The display unit according to claim 1, wherein the waterproof film is thermoplastic.

5. The display unit according to claim 1, wherein the waterproof film has light diffusion characteristics.

6. The display unit according to claim 1, wherein the waterproof film is achromatic.

7. The display unit according to claim 1, wherein the waterproof film closely contacts the mounting surface of the circuit board and the light emitting elements.

8. The display unit according to claim 7 comprising a sticky layer between the mounting surface of the circuit board and a surface of the waterproof film facing the mounting surface of the circuit board.

9. The display unit according to claim 7 comprising an adhesive layer between the mounting surface of the circuit board and a surface of the waterproof film facing the mounting surface of the circuit board.

10. The display unit according to claim 7, wherein at least one of the mounting surface of the circuit board and a surface of the waterproof film facing the mounting surface of the circuit board is plasma processed.

11. The display unit according to claim 7, comprising a primer layer between the mounting surface of the circuit board and a surface of the waterproof film facing the mounting surface of the circuit board.

12. The display unit according to claim 1, comprising a mask plate blocking external light.

13. The display unit according to claim 1, comprising a microlens gathering light emitted from the light emitting element.

14. A display device in which a plurality of the display units according to claim 1 are assembled.

15. The display device according to claim 14 comprising a grid frame combined with a plurality of frames that holds the display units.

16. A method for manufacturing a display unit comprising:
reducing a pressure in a vacuum container in which a waterproof film and a case placing a circuit board on which a plurality of light emitting elements are mounted are set;
covering, using the waterproof film, the light emitting elements, the case, and a surface on which the light emitting elements on the circuit board are mounted; and
increasing a pressure in the vacuum container.
